(19) United States
(12) Patent Application Publication
(10) Pub. No.: US 2007/0013451 A1
(43) Pub. Date: Jan. 18, 2007

(54) CIRCUITS FOR USE IN RADIO COMMUNICATIONS

(75) Inventors: Ariel Luzzatto, Holon (IL); Haim Friedlander, Rehovot (IL); Gadi Shirazi, Ramat Gan (IL)

Correspondence Address: MOTOROLA, INC;INTELLECTUAL PROPERTY SECTION, LAW DEPT, 8000 WEST SUNRISE BLVD, FT LAUDERDAL, FL, 33322, US

(73) Assignee: MOTOROLA, INC., Plantation, FL (US)

(21) Appl. No.: 11/534,093

(22) Filed: Sep. 21, 2006

(30) Foreign Application Priority Data
Apr. 21, 2004 (GB) 0408831.6
Apr. 19, 2005 (WO) PCT/US05/13207

(51) Int. Cl. H03L 7/00

(52) U.S. Cl. 331/16

(57) ABSTRACT

A frequency synthesiser circuit for use in wireless communications including a phase locked loop including a VCO (voltage controlled oscillator), wherein the synthesiser circuit includes a further oscillator which in operation is a free running oscillator at a frequency higher than the VCO and a mixer connected to receive input signals from the VCO and from the further oscillator and to combine such signals. Also described is a wireless communications transmitter or receiver incorporating the frequency synthesiser circuit.

### FIELDS OF THE INVENTION

This invention relates to circuits for use in wireless communications. In particular, it relates to frequency synthesiser circuits which incorporate a VCO (voltage controlled oscillator). Such circuits are useful in wireless transmitters and receivers for generating stable radio frequency signals.

### BACKGROUND OF THE INVENTION

Carrier frequency signals in RF (radio frequency) communications transmitters are conventionally generated by a frequency synthesiser circuit. Such a circuit usually includes a VCO connected in a phase locked loop (PLL). The loop, including the VCO, provides an appropriate stable output at a precisely defined frequency. The VCO usually employs one or more voltage controlled devices, e.g. a varactor (variable capacitance device), to provide tuning of the VCO to an output frequency related to an input control voltage. Such a circuit may also be employed to generate a local osillator signal for use in a radio receiver. In many cases the transmitter and receiver are combined in a single transceiver unit.

Wireless communications systems are now being designed for use at high frequencies, e.g. greater than 1 GHz. For example, local area networks in accordance with the 802.11a standard are being designed to operate in available operating bands close to 5 GHZ. With the use of such high frequencies, the design of suitable low-noise VCOs becomes more and more difficult, primarily due to the resistive loading caused by the voltage controlled device(s) on the VCO resonator.

This loading significantly reduces the resonator loaded Q-factor, with consequent increase of phase noise. This effect worsens as the frequency increases. However even at relatively low frequency bands such as VHF (136-174 MHz), the loading produced by the voltage controlled device is the limiting factor for phase noise performance, which in turn is the limiting factor for selectivity and coexistence specifications. (Coexistence is the capability of receiving a signal from a given transmitter in the presence of other nearby transmitters).

For instance, at VHF, where the resonator unloaded Q-factor is of the order of 150-600, the transistor loading reduces the Q-factor value to about half its unloaded value, and the loading by the voltage controlled device further reduces the Q-factor value to about a quarter of the already reduced value. For instance if the unloaded Q-factor is 150, the loaded Q-factor will be around 15. Starting with an unloaded Q-factor of 600, the loaded Q-factor is reduced to about 30. As the frequency increases, the reduction in Q-factor due to the voltage controlled device increases sharply.

In the prior art, known techniques involve splitting the VCO into sub-bands using multi-resonator arrangements, thus obtaining the effect of reducing the loading of the voltage controlled device on the resonator. These techniques are however both limited in effect and require a substantial amount of additional hardware and also software arrangements to switch the resonators. Undesirably, such additional hardware adds to the size and complexity of the circuit and such additional hardware and software adds to the cost.

### SUMMARY OF THE INVENTION

According to the present invention in a first aspect there is provided for use in wireless communications a frequency synthesiser circuit including a phase locked loop including a VCO (voltage controlled oscillator), wherein the synthesiser circuit includes a further oscillator which in operation is a free running oscillator at a mean frequency higher than that of the VCO and a mixer connected to receive input signals from the VCO and from the further oscillator and to combine such signals.

The mixer provides an output signal at a frequency which is a combination of the frequencies of its respective inputs. The mixer produces a first frequency component having (i) a sum of the respective input frequencies; and (ii) a difference between the respective input frequencies. Either component may be selected as the desired frequency. The unwanted component may be removed by filtering.

Desirably, the output signal provided by the mixer is passed through a RF filter, which may be a band pass, low pass or high pass filter or a combination of two or more such filters, to filter out individual frequency components directly from the VCO and the further oscillator and the undesired components of their combination. Whilst meeting these criteria, the filter may have a frequency pass band which is greater than 10 percent, e.g. 15 to 25 percent, of the desired output frequency.

The mean frequency of the further oscillator may be much higher than that of the VCO. For example, the mean frequency of the further oscillator may be at least 1.5 times, preferably at least 3 times, that of the VCO. In fact the VCO frequency may be as low as possible, provided that it covers the required frequency band of the output and any drift in the output frequency of the further free running oscillator (typically a few percent during the life of the oscillator). Thus, the mean frequency of the further oscillator may be typically ten times or more greater than that of the VCO.

The lower frequency VCO and the higher frequency further oscillator together provide a source of oscillations at their combined frequency (sum or difference as selected). The output signal from the mixer at this combined frequency, desirably passed through the RF filter, is an RF signal locked in phase by the phase locked loop. The phase locked loop may have, apart from the combined arrangement comprising the VCO, the further oscillator, the mixer and the RF filter, a known construction and operation.

Desirably, the further, free running oscillator includes a high Q-factor resonator, e.g. one having an unloaded Q-factor of at least 100, preferably at least 300, especially at least 500. Desirably, the Q-factor is reduced to not less than half of its unloaded value when loaded in the synthesiser circuit. Ceramic type resonators for use in this way are well known to those skilled in the art. An example of a suitable resonator is a coaxial resonator for use at 5 GHz as supplied by Temex of 29 Avenue de la Baltique, 91953 Les Ulis Cedex, France. Such a resonator, and an oscillator incorporating it, may beneficially contribute little to the phase noise of the circuit.

The present invention helps to solve or reduce the problem of loading and Q-factor reduction caused thereby as described earlier in the Background section. Since the higher frequency further oscillator is free running it contributes little to the circuit phase noise, since its load to the resonator is small as illustrated later. The VCO still contributes to loading phase noise. However, since it operates at a lower frequency, the VCO (together with the further free running oscillator which makes only a minor contribution to the phase noise) will exhibit a phase noise much better (lower level) than a VCO operating near to the desired output frequency and phase locked using the conventional approach of the prior art.

Although the invention is of greatest potential benefit when used to synthesise frequencies greater than 1 GHz, e.g. in one or more bands from 4 GHz to 6 GHz as used in WLAN, it is applicable also to much lower frequency bands, e.g. providing very low-noise oscillators for professional high-tier radios, for instance for use in emergency services, public safety and military applications, where strong coexistence and selectivity specifications are required, which may give the possibility of an improved oscillator noise performance that cannot be obtained with conventional methods. The output frequency synthesised may for example be 100 KHz or higher for VHF applications or 1 MHz or higher for higher frequency applications. Moreover, the invention can allow easy and straightforward extension of oscillators (in such applications over a range of frequencies) to multi-band operation, while keeping substantially constant phase-noise performance.

In the frequency synthesiser circuit according to the first aspect of the invention, the phase locked loop may include a frequency divider for dividing a frequency of an output of the mixer, preferably after passing through an RF filter, a phase detector for comparing the phase of an output of the frequency divider with a phase of a further divider receiving in operation an input from a reference oscillator, and a loop filter to filter an output voltage of the phase detector to produce a control voltage for supply to the VCO.

According to the present invention in a second aspect there is provided a transmitter and/or receiver for use in wireless communications which includes a frequency synthesiser according to the first aspect of the present invention. Such a transmitter may for example include a modulator which is operable to modulate an output signal provided by the frequency synthesiser, an RF amplifier to amplify an RF output signal of the modulator and an antenna to radiate an amplified output signal of the RF amplifier. Such a receiver incorporating the frequency synthesiser may include an antenna for receiving an input signal, a demodulator for demodulating the signal received by the antenna and a local oscillator for providing a reference signal for use in the demodulator, the local oscillator including a frequency synthesiser according to the first aspect.

Embodiments of the present invention will be described by way of example with reference to the accompanying drawings, in which:

### BRIEF DESCRIPTION OF THE DRAWINGS

FIG. 1 is a schematic block circuit diagram of a conventional phase locked loop frequency synthesiser circuit.

FIG. 2 is a schematic block circuit diagram of a phase locked loop frequency synthesiser circuit embodying the present invention.

### DESCRIPTION OF EMBODIMENTS OF THE INVENTION

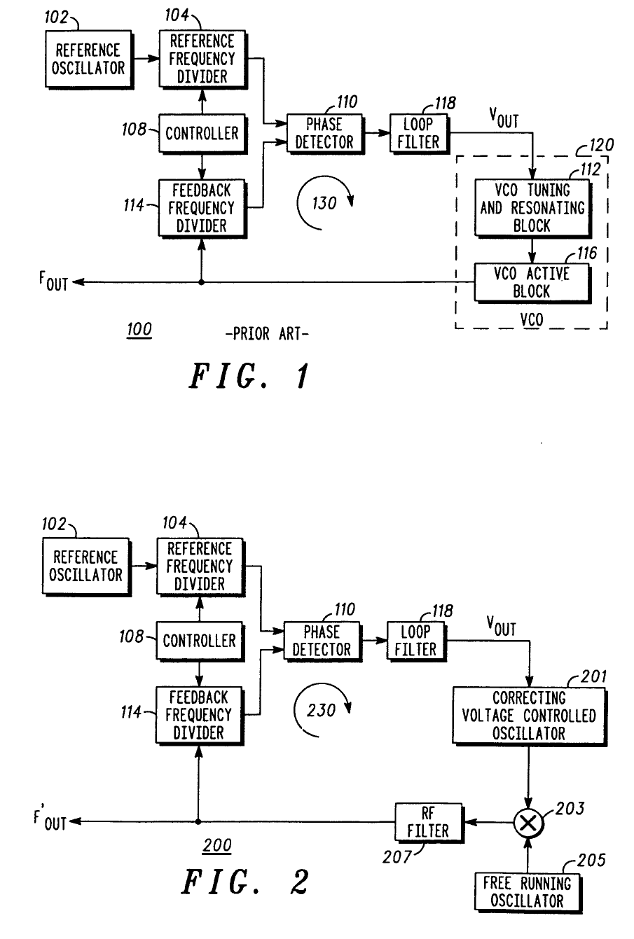

Reference is now made to FIG. 1, which is a schematic block circuit illustration of a conventional phase locked loop frequency synthesiser circuit, generally referenced as 100. The frequency synthesiser circuit 100 includes a reference oscillator 102, e.g. a crystal oscillator, a reference frequency divider 104, a controller 108, a phase detector 110, a loop filter 118, a VCO 120 and a feedback frequency divider 114. The VCO 120 includes as constituent parts a VCO tuning and resonating block 112 and a VCO active block 116.

The reference frequency divider 104 is connected to the reference oscillator 102, the controller 108 and the phase detector 110. The feedback frequency divider 114 is connected to the phase detector 110, the controller 108 and the VCO active block 116. The loop filter 118 is connected to the phase detector 110 and to the VCO tuning and resonating block 112. The VCO active block 116 is connected to the VCO tuning and resonating block 112 and to the feedback frequency divider 114. The loop including the VCO, the divider 114, the phase detector 110 and the loop filter 118 forms a phase locked loop 130.

The reference frequency divider 104 receives a signal, having a frequency F_{R}, from the reference oscillator 102. The reference frequency divider 104 further divides the frequency of this signal by N and provides the resultant signal, having the frequency F_{R}/N, to the phase detector 110. The feedback frequency divider 114 receives a feedback signal, having a frequency F_{OUT}, as an output from the VCO active block 116. The feedback frequency divider 114 further divides the frequency of this signal by M and provides the resultant signal, having the frequency F_{OUT}/M, to the phase detector 110. The phase detector 110 compares these two signals, generates a respective output control signal and provides it to the loop filter 118. Typically, the loop filter 118 is a low-pass filter. The loop filter 118 integrates the output control signal and provides a resultant output voltage V_{OUT} to the VCO tuning and resonating block 112. Depending on the value of V_{OUT}, related to the ratio of M to N, the VCO tuning and resonating block 112 adjusts the output frequency F_{OUT} so that it is equal to a desired value. The controller 108 provides control of the values of M and N and thereby provides adjustment of the value of V_{OUT} and F_{OUT}.

As described earlier, the prior art circuit 100 shows the problem of resonator loading and Q-factor reduction in the VCO 120 especially at high frequencies.

Reference is now made to FIG. 2, which is a schematic circuit diagram of a frequency synthesiser circuit 200 embodying the invention. Parts having the same reference numerals as in FIG. 1 operate in the same manner. In FIG. 2, the voltage V_{OUT} is applied to a correcting voltage controlled oscillator (CVCO) 201 the output from which is a RF signal which is applied as a first input to a mixer 203. A free running oscillator (FRO) 205 generates a further RF signal, of higher frequency than that from the CVCO 201, which is applied as a second input to the mixer 203. The mixer 203 combines the two input RF signals applied thereto and produces an output RF signal having components equivalent to (i) the sum; and (ii) the difference; of the respective frequencies of the two inputs. The output signal from the mixer 203 is fed to a RF filter 207 which may be a band pass filter which passes one of these components, e.g. the component which is the frequency sum, but not the other. The RF filter 207 also filters out RF components which are uncombined individual outputs of the CVCO 201 and the FRO 205. The band pass filter 207 produces an output signal at a required frequency F′_{OUT}.

Although the RF output signal of the CVCO 201 and that of the FRO 205 are constantly floating in frequency, the output RF frequency F′_{OUT} is locked and fixed. In fact, the CVCO 201 which is in a phase locked loop 230 (replacing the loop 130 of FIG. 1) eliminates the frequency/phase flotation of the FRO 205.

The RF filter 207 may conveniently be such as to pass a wide band of the output signal from the mixer 203, e.g. 20 percent or more of the frequency of the output of the mixer 203.

In a particular application, for use in WLAN applications where the desired output frequency is close to 5 GHz in a band having a bandwidth of 40 MHz, the FRO 205 may produce an output RF signal having a frequency of 4 (1−ε) GHz , where 0<ε<0.01 MHz, and the CVCO 201 may produce an output signal having a frequency in the range of from 1 (1−ε)+0.02 GHz to 1 (1+ε)+0.02 GHz. The RF filter 203 may pass frequencies in the range 4.5 GHz to 5.5 GHz. The resultant output frequency F′_{OUT} is in the range 4.98 GHz to 5.02 GHz.

The frequency range of the output signal of frequency F′_{OUT} (provided by the combination of the FRO 205 and CVCO 201 and the mixer 203 and band pass filter 207) may be changed simply by replacing the resonator of the FRO 205 and the RF filter 207. Beneficially, the phase noise performance is mainly limited by the CVCO 201 and can be relatively low because the phase noise of the CVCO 201 can be relatively low. This phase noise can for example be 20 to 30 dB lower than if a high frequency VCO only is used in the configuration of the prior art.

1. A frequency synthesiser circuit for use in wireless communications including a phase locked loop including a VCO (voltage controlled oscillator), wherein the synthesiser circuit includes a further oscillator which in operation is a free running oscillator at a frequency higher than the VCO and a mixer connected to receive input signals from the VCO and from the further oscillator and to combine such signals to produce an output signal that is locked in phase by the phase locked loop, but
wherein the VCO and the further oscillator are floating in frequency and not locked in phase by the phase locked loop.

2. A frequency synthesiser circuit according to claim 1 wherein in operation the mean frequency of the further oscillator is at least one of a) at least 1.5 times that of the VCO, b) at least 3 times that of the VCO, and c) at least 10 times that of the VCO.

3. A frequency synthesiser circuit according to claim 2 wherein in operation the output signal from the mixer is provided at a frequency which is a combined frequency of respective output signals from the VCO and the further oscillator.

4. A frequency synthesiser circuit according to claim 4 wherein the combined frequency is at least one of a) at least 100 KHz, b) at least 1 MHz, c) at least 1 GHz, and d) from 4 GHz to 6 GHz.

5. A frequency synthesiser circuit according to claim 4 wherein the further oscillator is operable to produce an output signal having a mean frequency of 4 (1−•) GHz, where 0<•<0.01 MHz, and the VCO is operable to produce an output signal having a mean frequency in the range of from 1 (1−•)+0.02 GHz to 1 (1+•)+0.02 GHz.

6. A frequency synthesiser circuit according to claim 1 wherein the mixer is connected to an RF filter to filter an output signal provided by the mixer.

7. A frequency synthesiser circuit according to claim 6 wherein the band pass filter has a frequency pass band which is greater than 10 percent of the desired output frequency of the synthesiser circuit.

8. A frequency synthesiser circuit according to claim 1 wherein the further oscillator is operable to have an unloaded Q-factor of at least 100.

9. A frequency synthesiser circuit according to claim 1 wherein the further oscillator is operable to have a loaded Q-factor of not less half that of its unloaded Q-factor.

10. A frequency synthesiser circuit according to claim 1 wherein the phase locked loop includes a first frequency divider for dividing a frequency of an output of the mixer, a phase detector for comparing the phase of an output of the frequency divider with a phase of a further divider receiving in operation an input from a reference oscillator, and a loop filter to filter an output voltage of the phase detector to produce a control voltage for supply to the VCO.
